(19) United States
(12) Patent Application Publication
(10) Pub. No.: US 2008/0008925 A1
(43) Pub. Date: Jan. 10, 2008

(54) Applications of double-walled nanotubes

(75) Inventors: Wei-Qiao Deng, Pasadena, CA (US); William A. Goddard, Pasadena, CA (US)

Correspondence Address: MINTZ, LEVIN, COHN, FERRIS, GLOVSKY AND POPEO, P.C, 1400 PAGE MILL ROAD, PALO ALTO, CA, 94304-1124, US

(73) Assignee: California Institute of Technology, Pasadena, CA (US)

(21) Appl. No.: 11/266,685

(22) Filed: Nov. 2, 2005

Related U.S. Application Data
(60) Provisional application No. 60/624,491, filed on Nov. 2, 2004.

(51) Int. Cl. H01M 4/96; H01L 21/00

(52) U.S. Cl. 429/44; 257/E51.04; 438/113

(57) ABSTRACT

A fuel cell electrode is provided which comprises catalyst particles and a nanotube composition comprising nanotubes which are predominantly double-walled. The catalyst particles preferably comprise platinum, and are preferably nanoparticles. The nanotubes preferably comprise carbon. A fuel cell is provided comprising an anode, a proton exchange electrolyte membrane, and a cathode, wherein the anode and/or the cathode comprise a catalyst support comprising nanotubes which are predominantly double-walled.

### CROSS-REFERENCE TO RELATED APPLICATIONS

This application claims priority under 35 U.S.C. § 119(e)(1) to Provisional U.S. Patent Application Ser. No. 60/624,491, filed Nov. 2, 2004. This provisional application is incorporated by reference in its entirety.

### TECHNICAL FIELD

This invention relates generally to nanotubes. It also pertains to areas in which nanotubes can be applied, for example integrated circuits and electrodes for electrochemical cells.

### BACKGROUND

Carbon nanotubes were discovered in 1991. They comprise roughly cylindrical molecules which have a framework of carbon atoms having roughly the structure of the atoms in a sheet of graphene, rolled to form a cylinder. Carbon nanotubes are typically 0.4 nm to a few tens of nanometers in diameter, and may be quite long in comparison to their diameter—10 micrometers or more.

Carbon nanotubes may comprise a single roughly cylindrical molecule or a number of such molecules arranged roughly concentrically. A nanotube with multiple roughly cylindrical molecules arranged roughly concentrically is referred to as a multiple-wall nanotube (MWNT). Those with two roughly cylindrical molecules arranged roughly concentrically are referred to as double-wall nanotubes (DWNTs). Nanotubes consisting primarily of one roughly cylindrical molecule are referred to as single-wall nanotubes (SWNTs).

Carbon nanotubes aroused considerable interest for a number of reasons. One of them is that theories of their electronic structure were set forth by scientists soon after their discovery. The nanotubes' cylindrical and axial symmetry allowed existing theories of the electronic structure of crystals to be adapted to nanotubes. Numerical computations of the electronic structures of carbon nanotubes have likewise been made. These early predictions suggested quite interesting mechanical and electrical properties, which subsequent empirical investigations have borne out.

It was found that the electronic structure of carbon nanotubes could be described in terms similar to the electronic structure of crystalline solids. Thus, the carbon atom valence electrons cease to be attached to individual atoms and spread out over a substantial part of the length of the nanotube, just as the valence electrons of a crystal spread out. The state of an electron depends on its wavevector k. The allowed states of the valence electrons form bands.

For certain nanotubes referred to as “semiconducting,” there is a gap between the filled and unfilled bands of allowed states, just as there is in semiconductor crystals like silicon and GaAs. In the ground states of those crystals, the lower energy bands are filled with valence electrons. Electrical conduction requires that some valence electrons be excited, thermally or otherwise, into a higher band of allowed states. Conductivity is thus relatively low and increases rapidly with temperature. Nanotubes which are semiconducting have the same general type of band structure as semiconductor crystals, with a gap between bands of filled and unfilled allowed states, and their conductivity exhibits similar behavior.

Other carbon nanotubes are referred to as “metallic.” In those nanotubes, the gap between the filled and unfilled bands is small or zero, and conductivity is higher and not as dependent on temperature.

Single-walled nanotubes of perfectly regular structure can be described by two integers (n, m). Consider a circle around the nanotube perpendicular to the nanotube's long direction. Imagine the nanotube unrolled and laid out atop a sheet of graphene, with the nanotube carbons lying atop graphene carbons. The circle will become a vector atop the graphene sheet. The numbers (n, m) are coordinates of this vector in the coordinate system defined by the graphene sheet's Bravais lattice. That lattice is defined by two vectors of the same length at 60 degree angles to each other, each going from the center of one six-membered carbon ring to an adjacent such ring. FIG. 1 shows the conceptual process of unrolling the nanotube and the meaning of the (n, m) values.

It is believed that perfectly regular single-walled carbon nanotubes are metallic if and only if their structure is defined by (n, m) with n−m divisible by 3.

In general it has not proven possible to synthesize only semiconducting or only metallic nanotubes. Instead, practical methods of growing nanotubes have resulted in mixtures of metallic and semiconducting nanotubes. Considerable effort has gone into the study of possible methods for separating the metallic and semiconducting nanotubes.

A number of books have been published about carbon nanotubes, for example Carbon Nanotubes: Science and Applications (M. Meyyappan ed., CRC Press 2005).

Following the discovery of carbon nanotubes, there has also been considerable interest in nanotubes made from a variety of other materials, for example boron, BN, WS₂, and MoS₂.

A fuel cell is an electrochemical cell which produces electrical energy from the chemical energy in a fuel. Despite being known as a means of generating electric energy for many years, fuel cells have generally been employed only for niche applications due to their cost. Compared to conventional generating plants, fuel cells potentially have important advantages in two respects: more efficient conversion of the chemical energy of the fuel to electrical energy and lower levels of pollution.

For general background on fuel cells, please refer to James Larminie & Andrew Dicks, Fuel Cell Systems Explained (Wiley 2d ed. 2003), and to EG&G Services et al., Fuel Cell Handbook (U.S. Department of Energy, 5th ed. 2000).

A common type of fuel cell is the proton exchange membrane fuel cell (PEMFC). Such cells are described, for example, in chapter 3 of the Fuel Cell Handbook referenced above. Proton exchange membrane fuel cells are fueled typically with hydrogen or methanol. For example, at the anode of a hydrogen-fueled PEMFC, a stream of hydrogen gas flows past. The reaction H₂→2H⁺+2e⁻ occurs. The proton H⁺ is transported through the proton exchange membrane. The electron e⁻ passes through the load of the fuel cell, providing electric power. At the cathode, the reaction 2H⁺+2e⁻+½O₂→H₂O typically occurs. The protons which have been transported through the proton exchange membrane reunite with electrons which have passed through the load and, together with oxygen, form water.

An important issue in fuel cells is the speed of the electrochemical reactions producing the energy. If the electrochemical reactions proceed slowly, then the current obtainable from the fuel cell will be limited. In general, it is necessary to employ catalysts and/or heat the fuel cell to several hundred degrees C. in order to obtain a usable fuel cell. A common catalyst is platinum. Due to the cost of platinum, much effort has gone into designing fuel cells which can achieve desirable levels of conversion of chemical energy into electric energy with a minimum amount of platinum. There has also been research into the use of platinum together with some other catalyst such as ruthenium. Platinum is generally used in the form of very fine particles dispersed on some sort of carbon support.

The use of carbon nanotubes has been suggested for fuel cell electrodes. See, e.g., U.S. Published Patent Application No. 2005/0181270.

It has also been suggested to use nanotubes as device components and as interconnect in integrated circuits. See, e.g., Jun Li et al., “Bottom-up approach for carbon nanotube interconnects,” Applied Physics Letters, 82:2491-2493 (2003); Shengdong Li et al., “Carbon Nanotube Growth for GHz Devices,” Proceedings of the 3rd IEEE Conference on Nanotechnology, 1, 256-259 (2003). These applications are generally envisaged as potentially going into production integrated circuits in about ten years, when feature sizes on integrated circuits are expected to be around 20 nm. At those small feature sizes, a number of problems arise with current technology. For example, peak current densities may need to be higher than they are today. Metal conductors of the types used today may be prone to thermal damage by electrical current at such small dimensions.

In both fuel cell electrode and integrated circuit applications of nanotubes, the conductivity of the nanotubes is important. That in turn is influenced by the metallic or semiconductor character of the nanotubes.

There is therefore a need in the art for superior nanotube compositions which have a more reliably controlled metallic or semiconductor character, and which are useful as electrode supports in fuel cells and for interconnect in integrated circuits.

### SUMMARY OF THE INVENTION

In one embodiment of the invention, a fuel cell electrode is provided which comprises catalyst particles and a nanotube composition comprising nanotubes which are predominantly double-walled. The catalyst particles preferably comprise platinum, and are preferably nanoparticles.

In a further embodiment of the invention, a fuel cell is provided comprising an anode, a proton exchange electrolyte membrane, and a cathode, wherein the anode and/or the cathode comprise nanotubes which are predominantly double-walled. The fuel cell may further comprise current collectors for the anode and cathode and delivery systems for fuel and oxidant.

In a further embodiment of the invention, an integrated circuit is provided which comprises a crystalline semiconductor substrate, electronic devices, layers of dielectric, and interconnect layers. The interconnect layers connect electronic devices according to a predetermined pattern. At least one of the interconnect layers comprises a carbon nanotube composition wherein the nanotubes are predominantly double-walled carbon nanotubes.

In a further embodiment of the invention, a method is provided for making integrated circuits. Electronic devices are formed on a semiconductor substrate. Dielectric layers are deposited upon the substrate. Interconnect layers, of which at least one comprises predominantly double-walled carbon nanotubes, are deposited or grown upon the substrate. The deposition of dielectric and interconnect layers may be interleaved. The substrate with deposited dielectric and interconnect is diced, packaged, and optionally tested.

### BRIEF DESCRIPTION OF THE FIGURES

FIG. 1 (prior art) depicts the manner in which a perfectly regular nanotube is described by integers (n, m).

FIG. 2 schematically depicts an exemplary fuel cell of the invention. The figure is not to scale.

FIGS. 3A-3D are transmission electron micrographs of platinum catalyst nanoparticles supported on double-walled carbon nanotubes, multi-walled carbon nanotubes, carbon black, and single-walled carbon nanotubes.

FIGS. 4A-4B depict the results of tests of the efficacy of different types of catalyst supports in a fuel cell for the oxygen reduction reaction and methanol oxidation reaction.

FIGS. 5A-5B depict the band structure of two double-walled carbon nanotubes as calculated using DFT and GGA with ultrasoft pseudo-potentials. The thick lines denote the HOMO and LUMO.

FIG. 6 depicts as a function of nanotube outer diameter the estimated number of double-walled nanotubes which are metallic, semiconducting, and “metallic 2” (meaning that the overall nanotube is metallic but one or both of the constituent SWNTs are not).

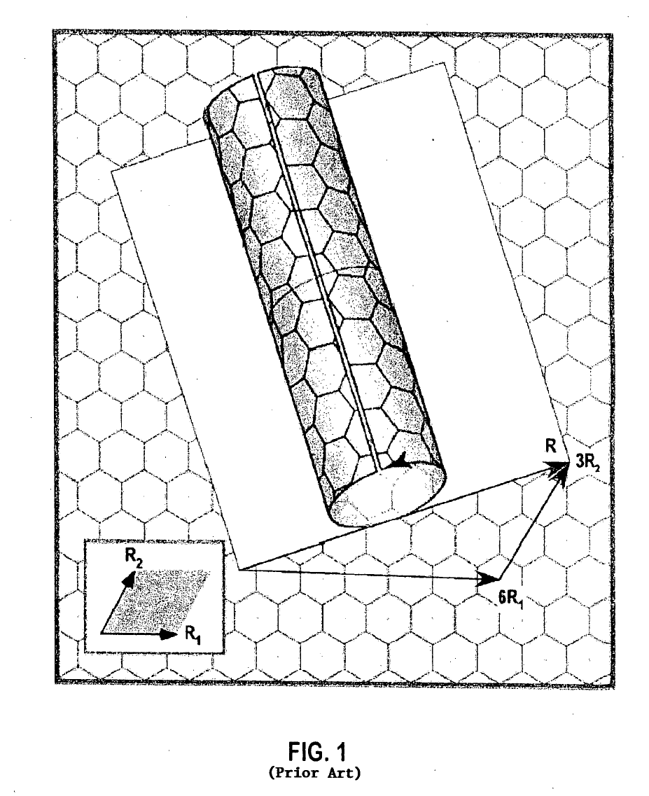

### DETAILED DESCRIPTION OF EMBODIMENTS OF THE INVENTION

Before describing the present invention in detail, it is to be understood that this invention is not limited to specific solvents, materials, or device structures, as such may vary. It is also to be understood that the terminology used herein is for the purpose of describing particular embodiments only, and is not intended to be limiting.

It must be noted that, as used in this specification and the appended claims, the singular forms “a,” “an,” and “the” include both singular and plural referents unless the context clearly dictates otherwise. Thus, for example, reference to “a nanotube” includes a plurality of nanotubes as well as a single nanotube, reference to “a temperature” includes a plurality of temperatures as well as single temperature, and the like.

“Optional” or “optionally” means that the subsequently described circumstance may or may not occur, so that the description includes instances where the circumstance occurs and instances where it does not.

The term “semiconductor substrate” refers to any substrate considered suitable for the manufacture of semiconductor devices and integrated circuits. The term also refers to the substrate during or after any of the various stages of treatment through which it goes during the process of semiconductor device and/or integrated circuit manufacture, for example during or after the deposition of dielectric or of interconnect conductors.

The term “mean outer diameter” of a collection of nanotubes refers to the sum of the outer diameters of the nanotubes in the collection divided by the number of nanotubes. In current practice, such diameters are commonly measured using transmission electron microscopy, but other techniques may also be used.

In one embodiment of the invention, a fuel cell electrode is provided which comprises catalyst particles and a nanotube composition comprising nanotubes which are predominantly double-walled. The catalyst particles preferably comprise platinum, and are preferably nanoparticles.

In a further embodiment of the invention, a fuel cell is provided comprising an anode, a proton exchange electrolyte membrane, and a cathode, wherein the anode and/or the cathode comprise nanotubes which are predominantly double-walled. The fuel cell may further comprise current collectors for the anode and cathode and delivery systems for fuel and oxidant.

As is shown in Examples 1 and 2 below, the use of predominantly double-walled carbon nanotubes offers an advantage over other supports in tests of electrode efficiency. In particular, using the measures of electrode efficiency employed in example 2, double-walled carbon nanotubes were found to be superior to conventional carbon black supports, to multi-walled carbon nanotubes, and to single-walled carbon nanotubes. This superiority was seen both in the oxygen reduction reaction and in the methanol oxidation reaction, showing the suitability of the double-walled nanotube support for the construction of both anodes and cathodes.

The superiority of the double-walled carbon nanotubes in fuel cell applications could be considered surprising. The catalytic activities of fuel cell electrodes depend at least in part on the electron transport channel and the interface properties. Therefore, conventional wisdom suggests that a good electronic conductor with high surface area should possess superior catalytic activities. However, from Table 1 of Example 1 below, we can see that the SWNT powders used in the tests of examples 1 and 2 have the highest surface area and best electric conductivity, yet the experimental results show that the SWNT powders have the worst catalytic activity.

From the superiority of double-walled carbon nanotubes it may be inferred that double-walled nanotubes of other types, such as boron, BN, WS₂, and MoS₂, may also offer advantages in fuel cell applications.

A common measure of the quality of a catalyst preparation for a fuel cell is obtained by cyclic voltammetry in the presence of a suitable concentration of fuel (for anodes) or oxidant (for cathodes). The catalyst preparation is often placed on a rotating electrode so as to make the results better reflective of the catalytic ability. The peak current observed in cyclic voltammetry can be used as a figure of merit for the comparison of electrodes. Where the focus is on the form of the carbon used to support the catalyst, a suitable baseline for comparison is the same catalyst deposited on carbon black, which is a common support material in use today.

Common methods for manufacturing nanotubes known so far divide broadly into arc discharge and laser ablation methods, on the one hand, and chemical vapor deposition (CVD) and plasma enhanced chemical vapor deposition (PECVD) on the other hand. The double-walled carbon nanotubes to be used to make the catalyst support of the invention may be produced by any suitable manufacturing process which produces predominantly double-walled nanotubes. The synthesis of double-walled nanotubes has been demonstrated in a number of articles, for example John Cumings et al., “Simplified synthesis of double-walled nanotubes,” Solid State Communications 126:359-362 (2003); Emmanuel Flahaut et al., “Gram-scale CCVD synthesis of double-walled nanotubes,” Chem. Commun. 2003:1442-1443; Jinquan Wei et al., “Preparation of highly pure double-walled carbon nanotubes,” J. of Materials Chemistry, 13:1340-1344 (2003); S. Bandow et al., “Turning peapods into double-walled nanotubes,” MRS Bulletin, April 2004, pp. 260-264; Carbon Nanotubes. Science and Applications section 3.5 (M. Meyyappan ed., CRC Press 2005); M. Endo et al., “‘Buckypaper’ from coaxial nanotubes,” Nature 33:476 (2005).

An exemplary process for the growth of double-walled carbon nanotubes employs arc discharge. In arc discharge processes generally a reaction chamber is filled with helium and/or argon at a subatmospheric pressure. Graphite rods serve as anode and cathode. The ends of the rods are spaced 1 to 4 mm apart, providing a gap in which an arc forms when a suitable DC current is driven between cathode and anode. The anode is consumed and a deposit containing nanotubes forms on the cathode. To maintain the arc, one moves the anode towards the cathode so as to keep the gap between the two roughly constant. It has been found (per Meyyappan as cited above) that DWNTs result if a suitable catalyst is placed in a hole in the center of the graphite anode. The catalyst can be a micronized powder of fused iron, cobalt, nickel and sulfur mixed with finely ground graphite.

An alternative exemplary growth process for double-walled carbon nanotubes employs chemical vapor deposition as described in Endo et al. above. A furnace is supplied with both Fe/MgO powder as a “nanotube catalyst” and Mo/Al₂O₃ as a “conditioning catalyst.” The nanotube catalyst is placed in the center of the furnace and the conditioning catalyst is placed towards one end. A 1:1 methane-argon gas mixture is fed into the furnace at 875° C. for ten minutes. The furnace is allowed to cool down to room temperature. The catalyst and nanotube material are removed from the furnace and purified by using hydrochloric acid to remove the iron catalyst and support and by using oxidation in air at 500° C. for 30 min to remove the amorphous carbon and chemically active SWNTs. Yield of DWNTs is stated to be 95%.

In the nanotube compositions of the invention it may be desired that the nanotubes be surface-modified. An exemplary surface modification is with COOH. In general, carbon nanotubes chemically resembled fullerenes so that techniques for surface modification which have been shown to be successful with fullerenes may be applicable to carbon nanotubes. Surface modification is discussed, for example, in Jian Chen et al., “Solution properties of single-walled nanotubes,” Science, 282:95-98 (1998).

As stated above, the catalyst is preferably composed predominantly of nanoparticles. An advantage of very fine catalyst particles is that a large surface area is offered upon which catalysis can occur. The catalyst may be deposited on the nanoparticles by any method which is suitable for the deposition of very fine particles, preferably nanoparticles. Preferably the catalyst is deposited from a solution containing appropriate precursors. Exemplary methods for depositing catalyst are found in Example 1 and in the paper Benny C. Chan et al., “Comparison of High-Throughput Electrochemical Methods for Testing Direct Methanol Fuel Cell Anode Electrocatalysts,” Journal of the Electrochemical Society, 152:A594-A600 (2005), which describes how to deposit catalysts comprising platinum and ruthenium.

The anode and cathode preferably comprise a catalyst and a nanotube composition on a conductive backing, preferably carbon. The catalyst may constitute a variable percentage of the total catalyst plus nanotube weight, for example 5 wt. %, 20 wt. %, 30 wt. %, 40 wt. %, 50 wt. %, or 60 wt. %. The anode and cathode are preferably on the order of some tens of micrometers thick. Making anodes and cathodes thin serves to lower the resistive loss through them. A binder may be used in the cathode and anode, for example polytetrafluoroethylene or Nafion. The anode, proton exchange membrane, and cathode are preferably sandwiched together to form what is commonly referred to as a membrane electrode assembly (MEA). This assembly may be formed, for example, by hot pressing two electrodes onto a proton exchange membrane. The overall thickness of the MEA is preferably roughly in the range of 30 to 300 μm.

The catalyst of the invention may be pure platinum or may be an alloy or combination of platinum with some other metal, such as Ru, Rh, Pd, Sn, or Mo. The catalyst may be different for the anode and the cathode. In other embodiments of the invention, non-platinum-containing catalysts may be employed.

The fuel cells of the invention may be designed to operate with hydrogen fuel, giving the reactions as set out above in the Background. They may also be designed for operation with methanol fuel or with other fuels such as ethanol. The anode reaction in methanol fuel cells may be CH₃OH+H₂O→CO₂+6H⁺+6e⁻; the cathode reaction may be 3/2O₂+6H⁺+6e⁻→3H₂O. Methanol fuel cells have the advantage that methanol fuel is easier to store and distribute than hydrogen on account of being liquid, and no reforming process is required. For further information regarding fuels such as methanol, please refer to U.S. Pat. No. 6,821,659.

The fuel cells of the invention may operate with the fuel and/or oxidizer at atmospheric pressure or at a different pressure. While higher pressures up to five times atmospheric pressure have been considered as a way of operating fuel cells with water-containing membranes at higher temperatures, since increasing the pressure increases the boiling point of water, it has been found that such higher pressures also have disadvantages. In general, a controllable pressure of fuel and oxidizer is preferred, using fluid flow control equipment known in the art which is suitable for operation at the temperatures and pressures being used.

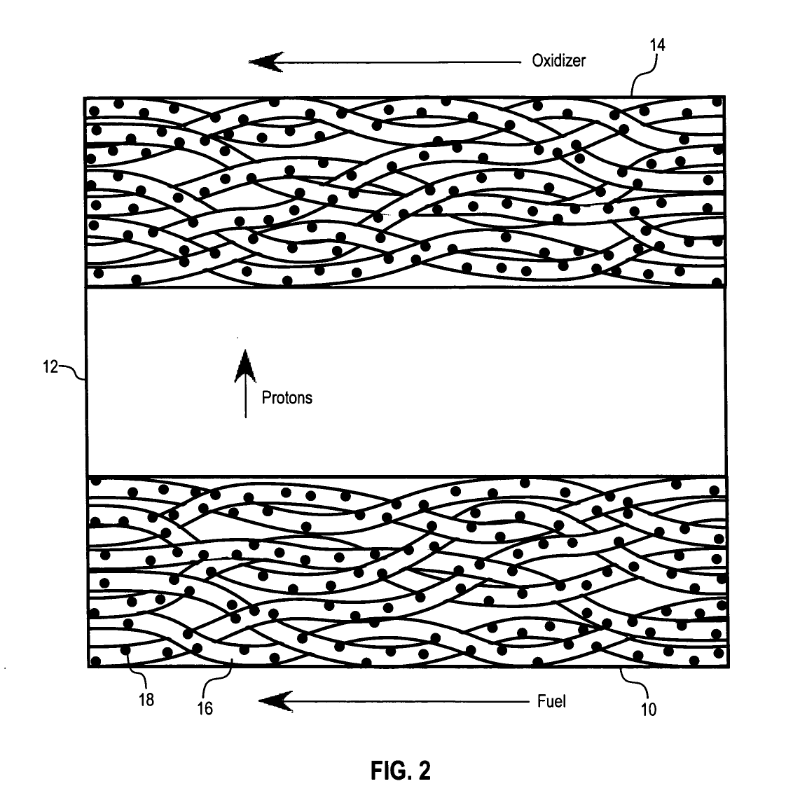

FIG. 2 depicts schematically (not to scale) an exemplary fuel cell of the invention. It is seen that there is a flow of fuel (for example hydrogen) past an anode 10. The flow of fuel is indicated by an arrow. The anode 10 is attached to a proton exchange membrane 12, which is in turn attached to a cathode 14. Past the cathode 14 there is a flow of oxidizer (for example air or pure oxygen), indicated by an arrow. Through the proton exchange membrane there is a flow of protons as a consequence of the electrochemical reactions taking place at anode and cathode. As discussed above, the anode and/or cathode preferably comprise predominantly double-walled carbon nanotubes 16 which serve to support a catalyst 18.

The fuel cells of the invention may preferably be stacked into assemblies. Their electrodes may be connected in series to achieve a higher voltage than each fuel cell individually achieves. They may also be arranged in an electrically parallel connection so that multiple fuel cells are each contributing current to a load. Combinations of series and parallel electrical connection are also possible. In such stacks, fuel and oxidizer may enter through a manifold so as to reach each individual fuel cell. The area between stacked fuel cells is conveniently occupied by a bipolar plate which is capable of serving as a separator between electrodes of adjacent fuel cells while forming passageways for gas or fuel supply to the electrodes.

Fuel cell assemblies may directly provide DC power to a load such as a regulated DC power supply or an electronic system. Alternatively they may drive a DC-to-AC inverter to provide AC power and potentially, for example, feed an electric power grid.

In general the fuel cells of the invention will preferably possess temperature controllers. The fuel cells may require in some circumstances external heating, particularly during the start up phase. The heat evolved in the fuel cells of the invention is preferably used to heat incoming gases or to heat other media, for example, through heat exchangers. The fuel cells of the invention may be part of a system which produces both steam and electric power (a combined heat and power system). Steam may naturally be produced at the cathode of such fuel cells as a result of the cathode reaction producing water.

In a further embodiment of the invention, a method is provided for making integrated circuits. Electronic devices are formed on a semiconductor substrate. Dielectric layers are deposited upon the substrate. Interconnect layers, of which at least one comprises predominantly double-walled carbon nanotubes, are deposited or grown upon the substrate. The deposition of dielectric and interconnect layers may be interleaved. The substrate with deposited dielectric and interconnect is diced, packaged, and optionally tested.

As has been noted above, there have been various proposals to made to employ carbon nanotubes in integrated circuits. Some of these proposals have involved the use of carbon nanotubes as part of electronic devices, for example transistors. In others, carbon nanotubes have been proposed to be used as interconnect. Embodiments of the present invention employ in particular double-walled carbon nanotubes.

One of the reasons why double-walled carbon nanotubes are believed to be especially advantageous for integrated circuit interconnect applications is that the commensurate double-walled carbon nanotubes of smaller diameter, less than about 1.3 nm, are inherently metallic in character, as determined by the quantum chemical computations which are described in Example 3 below. Such double-walled nanotubes may be metallic even though one or both of the single-walled nanotubes which make them up are semiconducting. This advantage is surprising and unexpected because it was believed that double-walled carbon nanotubes would take on the semiconducting or metallic character of the single-walled nanotubes which make them up.

Further attractions of carbon nanotubes for the integrated circuit interconnect application are that electronic conduction in metallic carbon nanotubes has been predicted to be ballistic, that is to say, free of resistance arising from scattering. A suitable composition of double-walled carbon nanotubes with a substantial proportion of smaller diameter nanotubes will be enriched in metallic nanotubes, as explained above, and thus will have a greater tendency to exhibit the benefits of ballistic conduction.

When carbon nanotubes are used as interconnect in integrated circuits, it is preferable that they have a low resistivity. As a result, it is preferred to use DWNTs which are generated by a manufacturing process which causes them to have small outer diameters. Ideally, the nanotubes would have a mean outer diameter of 1.3 nm or less. However, even if the nanotubes have a mean outer diameter higher than 1.3 nm, for example 1.6 nm or 1.8 nm or 2.0 nm, there is still a substantial advantage in that a considerable proportion of the nanotubes will have metallic character even if some are semiconducting. Control of nanotube outer diameter has been shown to be possible, for example, by controlling the size of the catalysts used in CVD and PECVD deposition. See, e.g., Chen Li Cheung et al., “Diameter-controlled synthesis of carbon nanotubes,” Journal of Physical Chemistry B, 106:2429-2433 (2003). There is a close correspondence between the size of the catalyst and the size of the resulting nanotubes. Thus, in the synthesis of nanotube compositions for use interconnect applications, it is preferred to use catalysts which comprise quite small nanoparticles, preferably on the order of 1 nm in diameter. Clusters comprising a Keggin ion, as described in Lei An et al., “Synthesis of Nearly Uniform Single-Walled Carbon Nanotubes Using Identical Metal-Containing Nanoclusters As Catalysts,” Journal of the American Chemical Society, 124:13688-13689 (2002), may be particularly advantageous for the synthesis of uniform-sized nanotubes.

In typical methods of the invention, on a semiconductor substrate (for example a 300 mm silicon wafer) electronic devices, for example MOS transistors, bipolar transistors, nanotube transistors, resistors, and capacitors, are formed by means of processes including steps such as ion implantation of dopants and growth of gate oxide. When devices are so formed, it is necessary to interconnect them in a way which results in the semiconductor substrate implementing a designed digital or analog or mixed digital/analog electronic circuit. Various types of dielectric films may also be used in the integrated circuit. The dielectrics may be coated with photoresist, exposed, and patterned. Room for lines, vias, and contacts may be etched using the patterned photoresist and a suitable etching system as for example a plasma or reactive ion type of etching. Interconnect may be laid down in the room that has been opened for lines, vias, and contacts. In the methods of the invention at least some of the interconnect comprises a nanotube composition which is predominantly double-walled. Remaining interconnect may, for example, be metallic and may use copper as it is employed conventionally today.

The predominantly double-walled carbon nanotube interconnect may be deposited by a variety of techniques. The common techniques in use today divide up into two broad categories. In one category, the nanotubes are made in a separate process and then added to the semiconductor surface. They may be, for example, suspended in a suitable solvent such as dimethylformamide (DMF) and then spin coated onto the semiconductor substrate. The suspended nanotubes may for example fill depressions in the semiconductor surface which are made permanently in dielectric. Following the spin coating, the solvent may be removed leaving a layer of nanotubes, for example in suitable depressions. The layer is patterned, for example by polishing away the portion of the layer lying above the depressions, or by an etching process of the type known to those of skill in the art. Exemplary methods of depositing and patterning layers of carbon nanotubes are disclosed, for example, in U.S. Pat. No. 6,942,921 to Rueckes et al.

In an alternative category of techniques for the deposition of nanotubes on a semiconductor surface, the nanotubes may be generated in situ. Suitable catalysts are placed in locations on the surface of the semiconductor substrate where it is desired that nanotubes grow. The placement of the catalyst may be carried out for example with conventional masking processes. The substrate is then subjected to an atmosphere containing suitable precursors (e.g., carbon monoxide, methane, acetylene) at an appropriate temperature, which causes the nanotubes to grow on the locations where it is desired that the nanotubes be located. Typically such processes require placing the substrate in a furnace at a temperature of several hundred degrees C. The Shendong Li et al. reference cited above gives a possible recipe for in situ growth of nanotubes. Possible further treatments of the deposited nanotubes, e.g., to remove catalyst as in the Endo et al. reference given above, may be desirable. In situ growth offers the possibility of a single nanotube or single nanotube bundle being the conductor for low currents, a possibility which has much to recommend it in terms of size and the avoidance of complications arising from electrical interfaces between differently oriented nanotubes within the overall interconnect. Various techniques have been used to orient the growth of nanotubes so that they are approximately parallel, for example by providing an electric field.

After the deposition of interconnect, the “hilly” interconnect and dielectric surface which results may be subjected to a flattening or polishing process such as chemical-mechanical polishing. Portions of the interconnect may be etched away, with the portions not being etched protected by photoresist. Commonly a number of layers of dielectric and interconnect will be deposited one on top of the other.

Following deposition of the interconnect and dielectric layers, the semiconductor substrate with the layers may be passivated and diced into individual integrated circuits, which are packaged and optionally tested before or after packaging. The process of packaging may, for example, include mechanically attaching the integrated circuit to a ceramic or other package, and connecting electrically pads formed on the integrated circuit to the pins or balls of the package. Other variants on these processes of semiconductor fabrication are known to those of skill in the art.

It is to be understood that while the invention has been described in conjunction with the preferred specific embodiments thereof, the foregoing description and the examples that follow are intended to illustrate and not limit the scope of the invention. Other aspects, advantages, and modifications within the scope of the invention will be apparent to those skilled in the art to which the invention pertains.

All patents, patent applications, and publications mentioned herein are hereby incorporated by reference in their entireties. However, where a patent, patent application, or publication containing express definitions is incorporated by reference, those express definitions should be understood to apply to the incorporated patent, patent application, or publication in which they are found, and not to the remainder of the text of this application, in particular the claims of this application.

### Example 1

### Preparation of Catalyst Supports

We investigated several carbon-based electro-catalyst support materials, SWNTs, DWNTs, MWNTs, and carbon black. Table 1 shows the electric properties and structural properties of the samples that we have used.

TABLE 1
Resistivities and surface areas of the carbon-based supports

| | SWNT | DWNT | MWNT | Carbon black |
|---|---|---|---|---|
| Resistivity (mΩ-cm) | 0.03 | 0.03-0.1 | 0.1 | 100 |
| Surface area (m²/g) | 1000 | 540 | 125 | 250 |

All the carbon-based materials used for catalyst support were obtained commercially. The SWNTs, DWNTs, and MWNTs were obtained from Nanocyl (Sambreville, Belgium). Vulcan XC-72 carbon black was purchased from Cabot Corporation (Boston, Mass.).

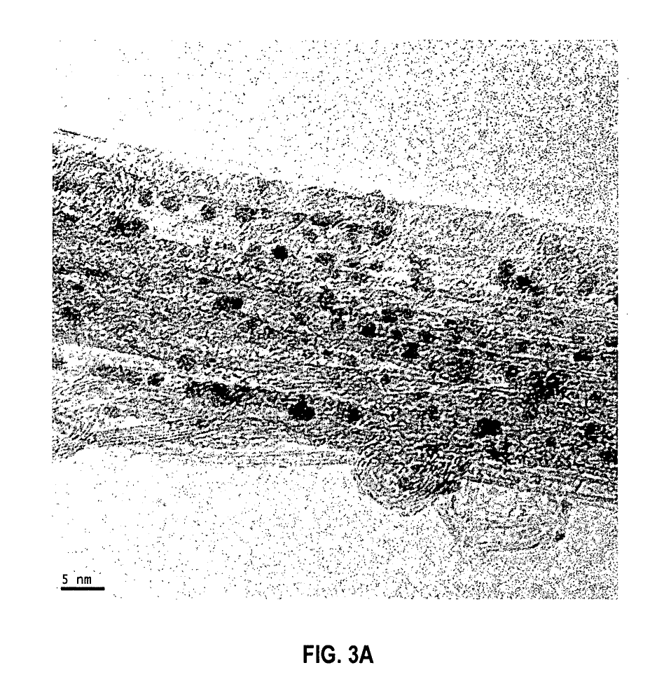

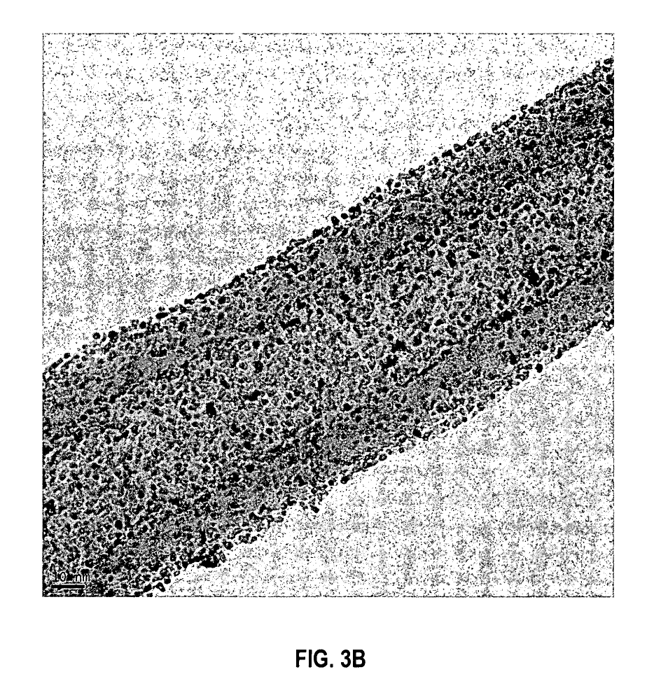

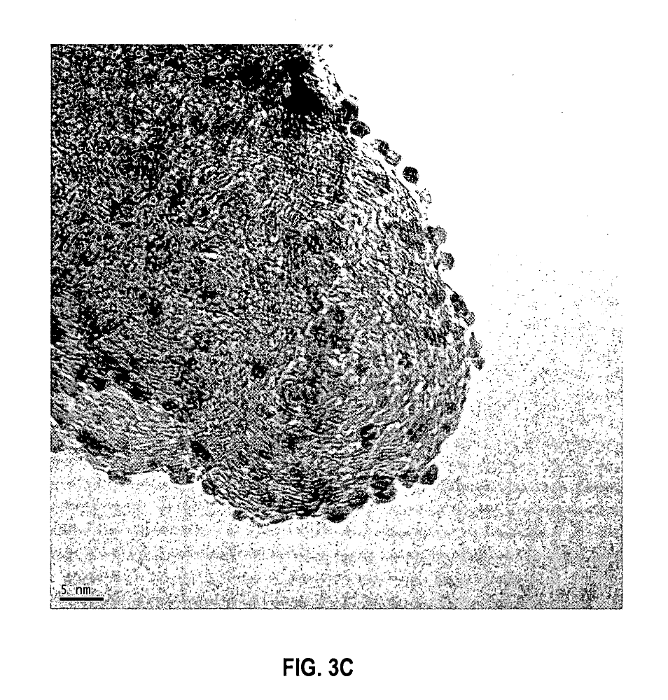

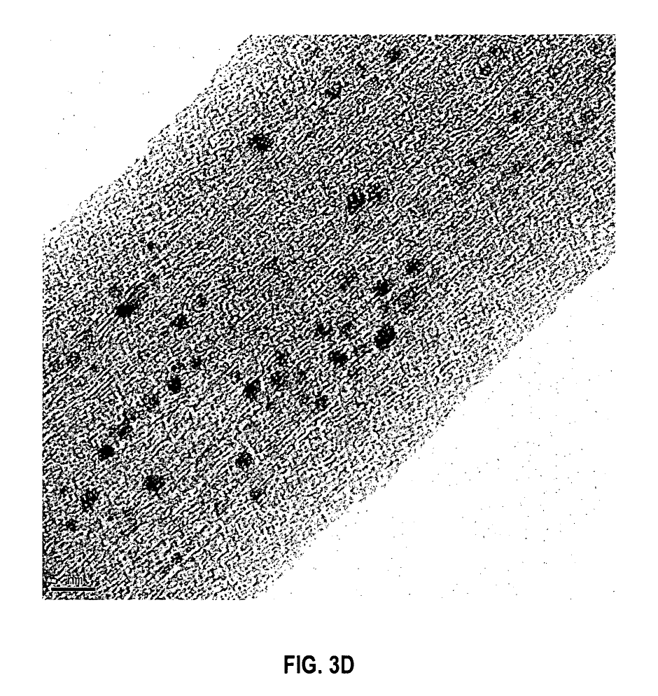

FIGS. 3A-3D shows typical TEM images of platinum supported on DWNTs. FIG. 3A depicts 30 wt % Pt/DWNTs, FIG. 3B depicts 30 wt % Pt/MWNTs, FIG. 3C depicts 30 wt % Pt/C, and FIG. 3D depicts 30 wt % Pt/SWNTs. FIG. 3A shows how the outer diameters of the DWNT supports range from 1 nm to 3 nm. DWNTs and SWNTs in our experiments occur in small bundles.

We used an EDAX analysis system to identify the well-dispersed dark spots in the TEM image as platinum nanoparticles. This analysis shows that the platinum nanoparticles prepared as described below have a narrow size distribution (2 nm to 3 nm) for all four supports.

To ensure a uniform platinum deposition on the outer walls of the nanotubes, all nanotubes used in these experiments were surface oxidized by sonication in H₂SO₄ for 1 hour and refluxing at 140° C. for 4 hours.

The deposition of platinum on various supports was realized using a modified polyglycol method. The support materials were suspended in ethylene glycol (EG) solution and mixed with a hexachloroplatinic acid solution by sonication. 1N NaOH solution in EG was added to adjust the solution to pH above 13. The solution was then heated at 140° C. for 3 h under refluxing conditions to reduce the platinum completely. After filtration, washing, and drying procedures, we obtained supported platinum catalysts with a metal loading of 30 wt. %.

### Example 2

### Evaluation of the Catalyst Supports

We used a rotating disk electrode system to investigate the catalytic properties of catalysts supported on different types of carbon nanotubes for two major fuel cell reactions: (1) the O₂ reduction reaction (ORR) and (2) the methanol oxidation reaction (MOR).

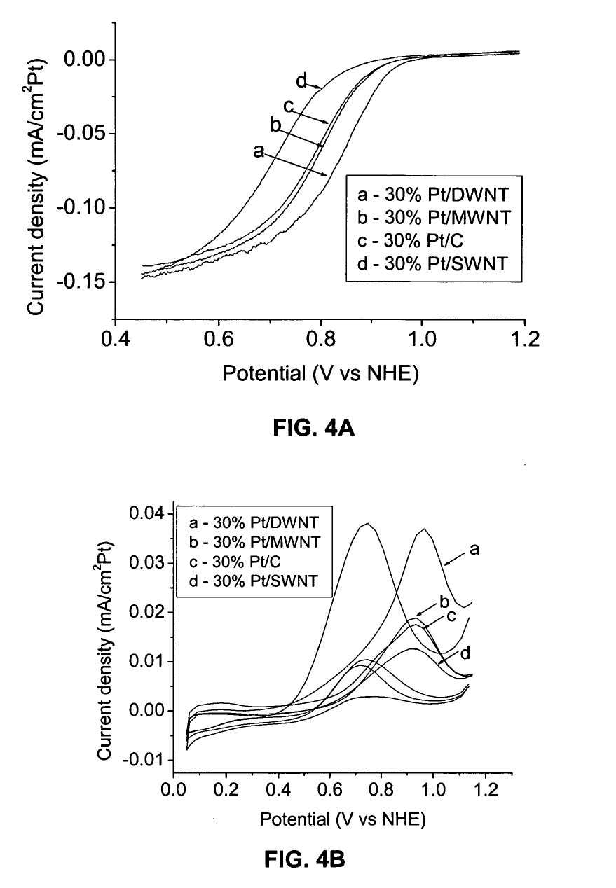

FIG. 4A shows the potentiodynamic currents of ORR for platinum catalyst on various supports, normalized by the electroactive surface area of platinum (obtained from the hydrogen desorption peak in the cyclic voltammogram in de-aerated 0.5 M H₂SO₄ electrolyte after correcting for double-layer charging current). The measured curve for ORR shifts positively in the order SWNT<Carbon black<MWNT<DWNT, suggesting an increase in the catalytic activity of ORR in the same order. To quantify this difference, we measured the half-wave potential as 0.69V<0.71V<0.73V<0.82V. The DWNTs exhibit the smallest overpotential for ORR, making them a promising support for PEMFC.

FIG. 4B shows the same trend for MOR in 1M CH₃OH+0.5M H₂SO₄. Here the peak current from the cyclic voltammetric curve indicates the intrinsic catalytic activity of the catalyst because for Pt catalyst the MOR reaction is kinetically controlled. The methanol oxidation current for Pt supported on the four carbon supports shows that the DWNTs are best.

Hence, we observed clearly that as an electro-catalyst support DWNTs offer a dramatic improvement over other carbon based support materials. Moreover, we find that for ORR, which involves four electrons, the enhancement of DWNT compared to MWNT is 110%. In contrast, for MOR (methanol oxidation), which involves six electrons, the enhancement ratio is ˜230%.

The electrochemical experiments were conducted in a rotating disk electrode system using the Solartron electrochemical interface (SI1287). We used an Ag/AgCl reference electrode and a Pt wire counter electrode. The working electrode (rotating disk electrode) was prepared by applying catalyst ink to the glassy carbon disk (Pine Instrument, 5 mm diameter). The catalyst ink was produced by ultrasonically dispersing 7.8 mg catalyst in 2 g ethanol for 30 min. Before each experiment the glassy carbon disk was polished to a mirror finish with a 0.05 μm alumina suspension, followed by ultrasonication in acetone and deionized (DI) water. An aliquot of 10 μL catalyst suspension was then pipetted onto the disk. After drying the suspension at 80° C., 10 μL of a 0.1 wt % Nafion® solution (diluted from 5 wt %, Ion Power Inc.) was pipetted on the electrode surface in order to attach the catalyst particles onto the glassy carbon substrate.

After preparation, the working electrode was immersed in deaerated (N2 purged) 0.5M H₂SO₄. The electrode potential was cycled 20 times between 0.05 and 1.1 V in order to produce a clean electrode surface and to measure the active surface area of Pt. For ORR, the electrolyte was then saturated with O₂ for the potentiodynamic measurement. For MOR, methanol was added to reach 1M concentration and cyclic voltammetry was conducted at 50 mV/s for 20 times with the last cycle recorded. Unless otherwise stated, all the electrode potentials were reported against NHE (normal hydrogen electrode).

### Example 3

### Numerical Computation of Bandgaps of Commensurate Small Diameter Double-Walled Carbon Nanotubes

Among the possible DWNT combinations smaller than 1.65 nm, there are 445 possible inner/outer combinations if we assume the inter-tube distance is 0.32 to 0.355 nm. We separate those candidates into two groups: commensurate ones and non-commensurate ones. In commensurate double-walled nanotubes, the inner and outer nanotubes have the same periodic unit. There are 20 possible commensurate combinations of inner and outer nanotubes among the 445 combinations mentioned above. In non-commensurate DWNTs, the inner and outer nanotubes have unrelated chiralities, so that the overall DWNT has a long repeating unit along the nanotube's length. Non-commensurate DWNTs are believed to be less stable than commensurate DWNTs and are thus less likely to occur when DWNTs are synthesized, although it cannot be guaranteed that they will not occur at all.

The commensurate nanotubes can have three different combinations of inner and outer nanotube character: metallic+metallic, semiconducting+metallic and semiconducting+semiconducting. We calculated the band structures of commensurate DWNTs by using DFT (density functional theory), employing GGA91 (the generalized gradient approximation) with an ultrasoft pseudo-potential. This method has also been used to calculate band structures of SWNTs, and is in good agreement with previous quantum-mechanical calculations and experimental results. Ultrasoft plane wave pseudopotentials may be generated with the optimization scheme of Lin et al., “Optimized and transferable nonlocal separable ab initio pseudopotentials,” Physical Review B, 47:4174 (1993). An energy cutoff of 280 eV and k-point sampling of 1×1×30 are usable for band structure studies. Calculations may be performed with the CASTEP code in the CERIUS2 software package.

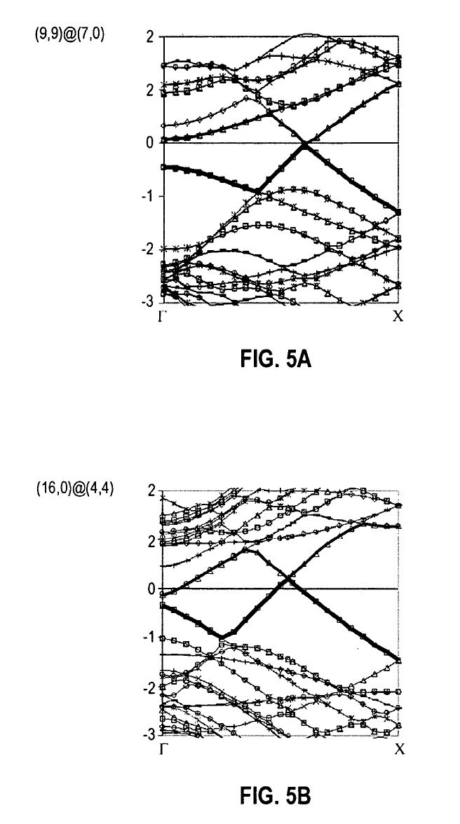

FIGS. 5A and 5B show the computed band structures for two types of double-walled carbon nanotubes, (9,9)@(7,0) and (16,0)@(4,4), which comprise one semiconducting and one metallic single-wall nanotube. The results of the computation show that both combinations are metallic with a zero band gap.

Table 2 below lists the computed band gaps for a number of DWNTs where both of the constituent single-walled nanotubes are semiconducting.

TABLE 2
Outer diameter and band gaps of smaller DWNTs

| DWNTs | Outer diameter (nm) | Band gap (GGA) eV |
|---|---|---|
| (13, 0)@(4, 0) | 1.02 | 0.00 |
| (14, 0)@(5, 0) | 1.10 | 0.00 |
| (15, 0)@(6, 0) | 1.18 | 0.00 |
| (16, 0)@(7, 0) | 1.26 | 0.00 |
| (17, 0)@(8, 0) | 1.33 | 0.32 |
| (18, 0)@(9, 0) | 1.41 | 0.00 |

Table 2 shows that all the listed DWNTs are metallic once the outer diameter of the DWNTs is smaller than 1.3 nm. It is believed that the DWNTs (13,0)@(4,0) and (14,0)@(5,0) are metallic because SWNT (4,0) and SWNT (5,0) experience sigma-pi hybridization with the enclosing SWNT. In the case of DWNT (16,0)@(7,0), it is believed that the nanotube is metallic because the inner tube shifts its HOMO (highest occupied molecular orbital) level up, and that level crosses with outer tube's LUMO (lowest unoccupied molecular orbital).

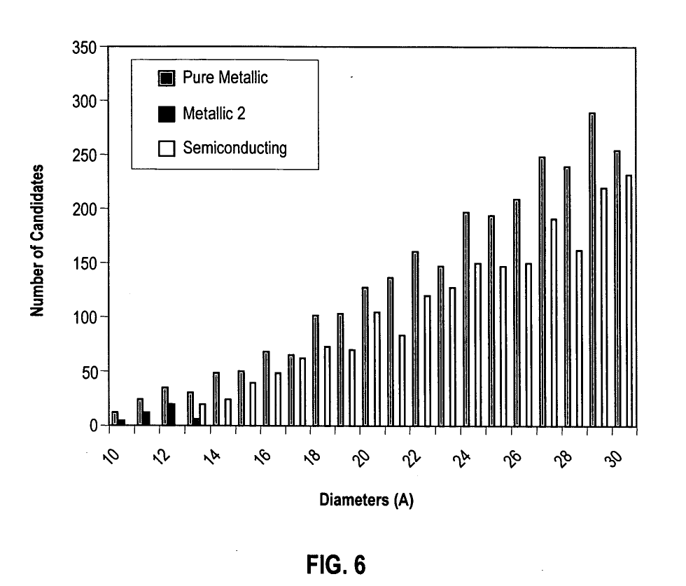

FIG. 6 is a histogram of DWNTs arranged by outer diameter. The figure separates the DWNTs in each outer diameter category into three groups: metallic ones, semi-semi combinations which are metallic, and semiconductors. As may be seen in the figure, all DWNTs below 1.25 nm are found to be metallic in the computation. Furthermore, even at higher diameters metallic nanotubes predominate.

The classification of FIG. 6 was carried out by computing the bandgap of each DWNT as the average of the bandgaps of the inner and outer SWNTs (known from the literature), minus an offset value E_{offset} reflective of the increase of the Fermi level of the inner SWNT. For example, in the (16,0)@(7,0) case the band gaps of (16,0) and (7,0) SWNTs are 0.57 and 0.34 eV respectively. The Fermi level shifts of (16,0) and (7,0) relative to the graphite Fermi level are 0.0 and 0.4 eV respectively. Therefore, the band gap of DWNT (16,0)@(7,0) is estimated to equal 0.5×(0.57+0.34)−0.4=0.05 eV. This result indicates that the (16,0)@(7,0) DWNT is very close to metallic and will have good conductivity at room temperature due to electrons being thermally excited into the conduction band. In fact, coupling between tubes is believed to decrease the band gap of this DWNT to 0 eV as calculated by GGA, which is more accurate that the estimate used in FIG. 6. Information useful for the approximate calculation of DWNT bandgaps may be obtained from the literature, for example from Bin Shan and Kyeongjae Cho, “First Principles Study of Work Functions of Single Wall Carbon Nanotubes,” Physical Review Letters, 94:236602 (2005).

1: A fuel cell electrode comprising catalyst particles and a nanotube composition which comprises nanotubes which are predominantly double-walled.

2: The fuel cell electrode of claim 1, wherein the catalyst particles comprise platinum.

3: The fuel cell electrode of claim 2, wherein the catalyst particles further comprise Ru, Rh, or Pd.

4: The fuel cell electrode of claim 1, wherein the catalyst particles are nanoparticles with an average diameter of 5 nm or less.

5: The fuel cell electrode of claim 4, wherein the catalyst particles are nanoparticles with a mean outer diameter of 3 nm or less.

6: The fuel cell electrode of claim 1, wherein the nanotubes comprise carbon.

7: The fuel cell electrode of claim 6, wherein the nanotubes are chemically surface modified.

8: The fuel cell electrode of claim 1, wherein the nanotubes comprise boron, BN, WS₂ or MoS₂.

9: The fuel cell electrode of claim 1, wherein the double-walled nanotubes have a mean outer diameter of 2 nm or less.

10: The fuel cell electrode of claim 1, wherein the catalyst particles and nanotube composition achieve a peak current in a cyclic voltammetry experiment using methanol fuel which is 50% greater than the peak current achieved with the same catalyst and carbon black in place of the nanotube composition.

11: The fuel cell electrode of claim 10, wherein the peak current is 100% greater than the peak current achieved with the same catalyst and carbon black in place of the nanotube composition.

12: A fuel cell comprising an anode, a proton exchange electrolyte membrane, and a cathode, wherein the anode and/or the cathode are as in claim 1.

13: The fuel cell of claim 12, wherein the anode reaction is a reduction of hydrogen.

14: The fuel cell of claim 12, wherein the anode reaction is a reduction of methanol.

15: The fuel cell of claim 12, wherein the anode, electrolyte membrane, and cathode form a membrane electrode assembly with a thickness of no more than about 300 μm.

16: The fuel cell of claim 12, wherein the catalyst comprises between 5% and 60% of the weight of the catalyst plus the nanotube composition.

17-21. (canceled)
